(19) United States
(12) Patent Application Publication
(10) Pub. No.: US 2020/0148845 A1
(43) Pub. Date: May 14, 2020

(54) METHOD FOR FORMING COVER FILM

(71) Applicant: JSR CORPORATION, Tokyo (JP)

(72) Inventor: Hitoshi OSAKI, Tokyo (JP)

(73) Assignee: JSR CORPORATION, Tokyo (JP)

(21) Appl. No.: 16/718,579

(22) Filed: Dec. 18, 2019

Related U.S. Application Data
(63) Continuation of application No. PCT/JP2018/023506, filed on Jun. 20, 2018.
(60) Provisional application No. 62/522,944, filed on Jun. 21, 2017.

(51) Int. Cl. C08J 5/18; C08F 297/02; H01L 21/02

(52) U.S. Cl. CPC C08J 5/18; C08F 297/026; C08J 2353/00; H01L 21/02282; H01L 21/02118

(57) ABSTRACT

A method for forming a cover film includes applying a composition including a first polymer and a solvent on a surface of a base material to form a coating film. The base material includes a surface layer which includes a first region and a second region having a surface condition that differs from a surface condition of the first region. The coating film is heated. A portion of the coating film is desorbed with a rinse agent after the heating. The portion is formed on the second region of the coating film. The first polymer includes a first structural unit represented by formula (1), or includes a monovalent organic group which bonds to at least one end of a main chain of the first polymer and which includes a nitrogen atom.

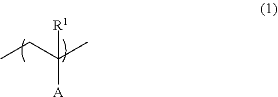

### CROSS-REFERENCE TO RELATED APPLICATIONS

The present application is a continuation application of International Application No. PCT/JP2018/023506, filed Jun. 20, 2018, which claims priority to U.S. Provisional Patent Application No. 62/522,944, filed Jun. 21, 2017. The contents of these applications are incorporated herein by reference in their entirety.

### BACKGROUND OF THE INVENTION

### Field of the Invention

The present invention relates to a method for forming a cover film.

### Discussion of the Background

In manufacture and the like of a semiconductor device, a cover film is formed in order to protect regions containing a metal in a surface layer of a base material such as a metal-containing substrate, a patterned metal-containing substrate or an inorganic insulating film.

In known materials for the cover film, a polymer such as a polyimide, a silicone resin and/or an epoxy resin are/is used so as to enable more convenient removal of the cover film with plasma ashing, etc. (Japanese Unexamined Patent Application, Publication No. 2012-089904 and see Japanese Unexamined Patent Application, Publication No. 2007-019528).

### SUMMARY OF THE INVENTION

According to an aspect of the present invention, a method for forming a cover film includes applying a composition including a first polymer and a solvent on a surface of a base material to form a coating film. The base material includes a surface layer which includes a first region and a second region having a surface condition that differs from a surface condition of the first region. The coating film is heated. A portion of the coating film is desorbed with a rinse agent after the heating. The portion is formed on the second region of the coating film. The first polymer includes a first structural unit represented by formula (1), or includes a monovalent organic group which bonds to at least one end of a main chain of the first polymer and which includes a nitrogen atom.

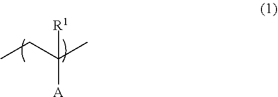

In the formula (1), R¹ represents a hydrogen atom, a methyl group, a fluorine atom or a trifluoromethyl group; and A represents a monovalent organic group comprising a nitrogen atom.

### BRIEF DESCRIPTION OF THE DRAWINGS

FIG. 1 shows a view illustrating highly selective formation by a method for forming a cover film of an embodiment of the present invention; and

FIG. 2 shows a view illustrating highly selective formation by a method for forming a cover film of the embodiment of the present invention.

### DESCRIPTION OF THE EMBODIMENTS

According to an embodiment of the invention, a method for forming a cover film comprises: providing a base material comprising a surface layer which comprises a first region and a second region having a surface condition that differs from a surface condition of the first region; applying a composition comprising a first polymer and a solvent on a surface of the base material; heating a coating film formed by the applying; and desorbing with a rinse agent a portion formed on the second region of the coating film after the heating, wherein the first polymer comprises a first structural unit represented by formula (1), or comprises a monovalent organic group that bonds to at least one end of a main chain and comprises a nitrogen atom,

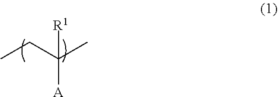

wherein, in the formula (1), R¹ represents a hydrogen atom, a methyl group, a fluorine atom or a trifluoromethyl group; and A represents a monovalent organic group comprising a nitrogen atom.

The “organic group” as referred to herein means a group that includes at least one carbon atom. The “main chain” as referred to herein means a longest atom chain of a polymer.

The method for forming a cover film according to the embodiment of the present invention enables a cover film having a great film thickness and high density to be formed conveniently. The cover film can be highly selectively formed in a part of regions among regions having different surface conditions from one another although it is difficult to accomplish both favorable physical properties and highly selective formation. Therefore, the method for forming a cover film can be suitably used for working processes of semiconductor devices and the like, for which further progress of miniaturization is expected in the future.

Hereinafter, an embodiment of the method for forming a cover film of the present invention is explained in detail.

Method for Forming Cover Film

The method for forming a cover film of the embodiment of the invention includes: providing a base material (hereinafter, may be also referred to as “base material (X)”) comprising a surface layer which comprises a first region (hereinafter, may be also referred to as “region (I)”) and a second region (hereinafter, may be also referred to as “region (II)”) having a surface condition that differs from a surface condition of the region (I) (hereinafter, may be also referred to as “providing step”); applying a composition (hereinafter, may be also referred to as “composition (I)”) comprising a first polymer (hereinafter, may be also referred to as “(A) polymer” or “polymer (A)”) and a solvent (hereinafter, may be also referred to as “(B) solvent” or “solvent (B)”) on a surface of the base material (X) (hereinafter, may be also referred to as “applying step”); heating a coating film (hereinafter, may be also referred to as “coating film (Y)”) formed by the applying (hereinafter, may be also referred to as “heating step”); and desorbing with a rinse agent a portion formed on the region (II) of the coating film (Y) after the heating (hereinafter, may be also referred to as “desorbing step”), wherein the polymer (A) comprises a first structural unit (hereinafter, may be also referred to as “structural unit (I)”) represented by formula (1), or comprises a monovalent organic group that bonds to at least one end of a main chain and comprises a nitrogen atom (hereinafter, may be also referred to as “terminal group (I)”).

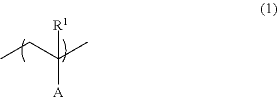

In the above formula (1), R¹ represents a hydrogen atom, a methyl group, a fluorine atom or a trifluoromethyl group; and A represents a monovalent organic group containing a nitrogen atom (hereinafter, may be also referred to as “side chain group (I)”).

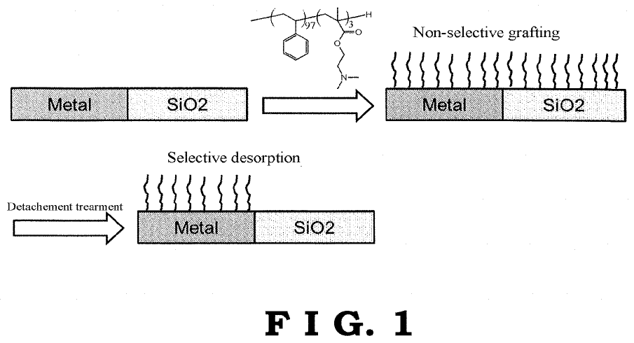

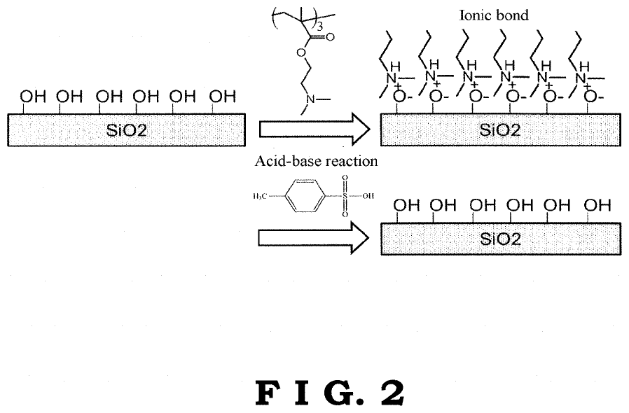

According to the method for forming a cover film, by virtue of: including each step described above; and the composition (I) containing the polymer (A), convenient and highly selective formation of the cover film having a great film thickness and high density is enabled. Although not necessarily clarified and without wishing to be bound by any theory, the reason for achieving the effects described above due to the method for forming a cover film involving the aforementioned constitution may be supposed as in the following, for example. It is considered that since the polymer (A) exhibits, owing to the nitrogen atom in the side chain group (I) or the terminal group (I), very strong interaction to various regions each containing a metal, SiO₂ or the like in the surface layer of the base material (X), the polymer (A) is non-selectively grafted in various regions as shown in FIG. 1, and therefore a film thus formed has a great film thickness and becomes highly dense. On the other hand, the formed film is subjected to a detachment treatment with a rinse agent in the desorbing step, whereby it is believed that the film is desorbed selectively in a part of regions among the regions having different surface conditions as shown in FIG. 1, and consequently the cover film is formed conveniently and highly selectively. The selective detachment of the film with the rinse agent is believed to occur resulting from the difference in type of the element in each region, and is considered to occur on the basis of the difference in the mode of bonding of the nitrogen atom in the polymer (A) to, for example, a metal atom, a nonmetal atom or the like. The bonding of a metal atom and a nitrogen atom is generally a coordinate bond, whereas a nonmetal atom in SiO₂ or the like (such as an —OH group) is envisaged to bond to a nitrogen atom via an ionic bond, as shown in FIG. 2. Consequently, it is believed that the ionic bond disappears by an action of, for example, an acid, a base or the like in the rinse agent, thereby leading to the detachment of the film.

Hereinafter, each step will be described.

Providing Step

In this step, the base material (X) having a surface layer including the region (I) and the region (II) having a surface condition that differs from a surface condition of the region (I) is prepared.

The expression “having a surface condition that differs” as referred to herein means that, for example, states of the presence of elements on the surface are different due to a difference in materials and/or shapes in the surface layer, a difference in the surface treatment and the like, of the base material (X). Of these, in light of further augmentation of the effects by the method for forming a cover film, the region (I) is different from the region (II) preferably in materials in the surface layers, and more preferably in types of atoms present in the surface layers.

The region (I) is exemplified by a region that includes a metal atom (hereinafter, may be also referred to as “metal atom (A)”), and the like.

The metal atom (A) is not particularly limited as long as it is an atom of a metal element. Silicon and boron do not fall under the category of the metal atom (A). Examples of the metal atom (A) include copper, iron, zinc, cobalt, aluminum, tin, tungsten, zirconium, titanium, tantalum, germanium, molybdenum, ruthenium, gold, silver, platinum, palladium, nickel, and the like. Of these, titanium, copper, cobalt, aluminum or tungsten is preferred, and tungsten is more preferred.

The metal (A) may be included in the region (I) in the form of, for example, a metal simple substance, an alloy, a metal nitride, a metal oxide, a silicide or the like.

Examples of the metal simple substance include simple substances of metals such as copper, cobalt, aluminum and tungsten, and the like.

Examples of the alloy include a nickel-copper alloy, a cobalt-nickel alloy, a gold-silver alloy, and the like.

Examples of the metal nitride include titanium nitride, tantalum nitride, iron nitride, aluminum nitride, and the like.

Examples of the metal oxide include tantalum oxide, aluminum oxide, iron oxide, copper oxide, and the like.

Examples of the silicide include iron silicide, molybdenum silicide, and the like.

Of these, the metal simple substance or the metal nitride is preferred, the metal simple substance is more preferred, and tungsten is still more preferred. As the base material (X) having a surface layer that includes the region (I), for example, a substrate of a metal simple substance is preferred, and a substrate of tungsten is more preferred.

The region (II) is exemplified by a region that substantially consists of a nonmetal atom (hereinafter, may be also referred to as “nonmetal atom (B)”) and the like. Examples of the nonmetal atom (B) include silicon, boron, carbon, oxygen, nitrogen, hydrogen, and the like.

The nonmetal atom (B) may be included in the region (II) in the form of, for example, a nonmetal simple substance, a nonmetal oxide, a nonmetal nitride, a nonmetal oxynitride, a nonmetal oxycarbide or the like.

Examples of the nonmetal simple substance include simple substances of nonmetals such as silicon, boron and carbon, and the like.

Examples of the nonmetal oxide include silicon dioxide (SiO₂), hydrolytic condensation products of hydrolyzable silane such as tetraalkoxysilane, e.g., tetraethoxysilane (TEOS), as well as boron oxide, and the like.

Examples of the nonmetal nitride include silicon nitride, boron nitride and the like.

Examples of the nonmetal oxynitride include silicon oxynitride, boron oxynitride, and the like.

Examples of the nonmetal oxycarbide include silicon oxycarbide (SiOC) and the like.

Of these, the simple substance, oxide, nitride, oxynitride or oxycarbide of silicon is preferred, and the silicon simple substance, silicon dioxide, a hydrolytic condensation product of hydrolyzable silane, silicon nitride, silicon oxynitride or silicon oxycarbide is more preferred.

Examples of the base material (X) having a surface layer that includes the region (II) include a Bare-Si substrate, SiO₂ substrate, SiN substrate, SiOC substrate, TEOS substrate, and the like.

A mode of the arrangement of the region (I) and/or the region (II) on the surface layer of the base material (X) is not particularly limited, and is exemplified by a plate, spots, stripes, or the like in a planar view. The size of the region (I) and the region (II) is not particularly limited, and the regions may have an appropriate desired size.

The shape of the base material (X) is not particularly limited, and may be an appropriate desired shape such as a plate (in case of the substrate) or a sphere.

It is preferred that the surface of the base material (X) is washed beforehand with, for example, an about 5% by mass aqueous citric acid solution.

Applying Step

In this step, the composition (I) containing the polymer (A) and the solvent (B) is applied on the surface of the base material (X).

The application procedure of the composition (I) may be, for example, spin coating, or the like.

Composition (I)

The composition (I) contains the polymer (A) and the solvent (B). The composition (I) may also contain other component(s) in addition to the polymer (A) and the solvent (B), within a range not leading to impairment of the effects of the present invention. Each component is as described below.

(A) Polymer

The polymer (A) has either the structural unit (I), or the terminal group (I). The polymer (A) may also have a second structural unit (hereinafter, may be also referred to as “structural unit (II)”) described later, and may also have a structural unit other than the structural unit (I) and the structural unit (II) (other structural unit). The polymer (A) may have one, or two or more types of each structural unit and the terminal group (I). The structural unit (I), the terminal group (I), the structural unit (II), and the like are as described below.

Structural Unit (I)

The structural unit (I) is represented by the following formula (I).

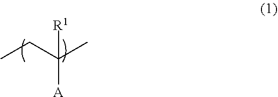

In the above formula (1), R¹ represents a hydrogen atom, a methyl group, a fluorine atom or a trifluoromethyl group; and A represents a side chain group (I).

In light of a degree of copolymerization of a monomer that gives the structural unit (I), R¹ represents preferably a hydrogen atom or a methyl group, and more preferably a methyl group.

The nitrogen atom (A) in the side chain group (I) preferably has an unshared electron pair, and preferably does not constitute a cyano group.

The nitrogen atom (A) having the unshared electron pair is exemplified by: a nitrogen atom to which one to three atom(s) other than a hydrogen atom bonds/bond via a single bond; a nitrogen atom in an aromatic heterocyclic group; and the like.

The lower limit of a pKₐ of a conjugate acid of the nitrogen atom (A) is preferably 3, more preferably 5, still more preferably 7, and particularly preferably 9. The upper limit of the pKₐ is, for example, 14. When the pKₐ of the conjugate acid of the nitrogen atom (A) falls within the above range, the film thickness and the density of the cover film can be further increased. The conjugate acid of the nitrogen atom (A) as referred to herein means a product derived by coordinate bonding of a proton to an unshared electron pair included in the nitrogen atom (A).

Examples of the side chain group (I) include: a group (α) that includes a divalent nitrogen atom-containing group between two adjacent carbon atoms of a monovalent hydrocarbon group having 1 to 20 carbon atoms; a group obtained by substituting a part or all of hydrogen atoms included in the hydrocarbon group and group (α) with a monovalent nitrogen atom-containing group; and the like. The side chain group (I) may further include a divalent group containing a hetero atom other than a nitrogen atom between two adjacent carbon atoms of the hydrocarbon group, and/or a part or all of the hydrogen atoms included in the hydrocarbon group and the group (α) may be further substituted with a monovalent group containing a hetero atom other than a nitrogen atom.

The “hydrocarbon group” as referred to herein may include a chain hydrocarbon group, an alicyclic hydrocarbon group and an aromatic hydrocarbon group. The “hydrocarbon group” may be either a saturated hydrocarbon group or an unsaturated hydrocarbon group. The “chain hydrocarbon group” as referred to herein means a hydrocarbon group not including a cyclic structure but being constituted with only a chain structure, and both a linear hydrocarbon group and a branched hydrocarbon group may be included. The “alicyclic hydrocarbon group” as referred to herein means a hydrocarbon group that includes, as a ring structure, not an aromatic ring structure but an alicyclic structure alone, and may include both a monocyclic alicyclic hydrocarbon group and a polycyclic alicyclic hydrocarbon group. In this regard, it is not necessary for the alicyclic hydrocarbon group to be constituted with only an alicyclic structure; it may include a chain structure in a part thereof. The “aromatic hydrocarbon group” as referred to herein means a hydrocarbon group that includes an aromatic ring structure as a ring structure. In this regard, it is not necessary for the aromatic hydrocarbon group to be constituted with only an aromatic ring structure; it may include a chain structure or an alicyclic structure in a part thereof. The number of “ring atoms” as referred to herein means the number of atoms constituting the ring in an alicyclic structure, an aromatic ring structure, an aliphatic heterocyclic structure or an aromatic heterocyclic structure, and in the case of a polycyclic ring structure, the number of “ring atoms” means the number of atoms constituting the polycyclic ring.

The monovalent hydrocarbon group having 1 to 20 carbon atoms is exemplified by a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, and the like.

Examples of the monovalent chain hydrocarbon group having 1 to 20 carbon atoms include:

alkyl groups such as a methyl group, an ethyl group, a n-propyl group and an i-propyl group;

alkenyl groups such as an ethenyl group, a propenyl group and a butenyl group;

alkynyl groups such as an ethynyl group, a propynyl group and a butynyl group; and the like.

Examples of the monovalent alicyclic hydrocarbon group having 3 to 20 carbon atoms include:

monocyclic alicyclic saturated hydrocarbon groups such as a cyclopentyl group and a cyclohexyl group;

monocyclic alicyclic unsaturated hydrocarbon groups such as a cyclopentenyl group and a cyclohexenyl group;

polycyclic alicyclic saturated hydrocarbon groups such as a norbornyl group, an adamantyl group and a tricyclodecyl group;

polycyclic alicyclic unsaturated hydrocarbon groups such as a norbornenyl group and a tricyclodecenyl group; and the like.

Examples of the monovalent aromatic hydrocarbon group having 6 to 20 carbon atoms include:

aryl groups such as a phenyl group, a tolyl group, a xylyl group, a naphthyl group and an anthryl group;

aralkyl groups such as a benzyl group, a phenethyl group, a naphthylmethyl group and an anthrylmethyl group; and the like.

Examples of the divalent nitrogen atom-containing group include —NH—, —NR′—, —C═N—, and the like, wherein R′ represents a monovalent hydrocarbon group having 1 to 10 carbon atoms.

Examples of the monovalent nitrogen atom-containing group include —NH₂, —NHR″, —NR″₂, and the like, wherein R″ represents a monovalent hydrocarbon group having 1 to 10 carbon atoms.

The hetero atom constituting the monovalent or divalent group containing the hetero atom other than a nitrogen atom is exemplified by an oxygen atom, a sulfur atom, a phosphorus atom, a silicon atom, a halogen atom, and the like. Examples of the halogen atom include a fluorine atom, a chlorine atom, a bromine atom, an iodine atom, and the like.

Examples of the divalent group containing the hetero atom other than a nitrogen atom include —O—, —CO—, —S—, —CS—, a group obtained by combining two or more of these, and the like. Of these, —O— is preferred.

Examples of the monovalent group containing the hetero atom other than a nitrogen atom include: halogen atoms such as a fluorine atom, a chlorine atom, a bromine atom and an iodine atom; a hydroxy group; a carboxy group; a sulfanyl group; and the like.

As the side chain group (I), a group represented by the following formula (i) is preferred.

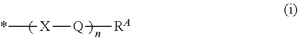

In the above formula (i), X represents a single bond, —COO—, —CO—, —O—, —NH—, —NHCO— or —CONH—; Q represents a single bond or a divalent hydrocarbon group having 1 to 20 carbon atoms; R^{A} represents a monovalent primary, secondary or tertiary amino group having 0 to 20 carbon atoms, or a monovalent nitrogen-containing heterocyclic group having 5 to 20 ring atoms; n is an integer of 0 to 10, wherein in a case in which n is no less than 1, Q does not represent a single bond; and * denotes a binding site to a carbon atom to which R¹ bonds in the above formula (1).

X represents preferably a single bond or —COO—, and more preferably —COO—.

Examples of the divalent hydrocarbon group having 1 to 20 carbon atoms which may be represented by Q include groups similar to the divalent hydrocarbon group having 1 to 20 carbon atoms exemplified as A in the above formula (1), and the like.

Q represents preferably a divalent hydrocarbon group, more preferably an alkanediyl group, and still more preferably an ethanediyl group.

Examples of the monovalent primary, secondary or tertiary amino group having 0 to 20 carbon atoms which may be represented by R^{A} include:

a primary amino group represented by —NH₂;

secondary amino groups such as a methylamino group, an ethylamino group, a cyclohexylamino group and a phenylamino group;

tertiary amino groups such as a dimethylamino group, a diethylamino group, a dicyclohexylamino group and a diphenylamino group; and the like.

Examples of the monovalent nitrogen-containing heterocyclic group having 5 to 20 ring atoms which may be represented by R^{A} include:

nitrogen-containing aliphatic heterocyclic groups such as an azacyclopentyl group, an azacyclohexyl group, a 3,3,5,5-tetramethylazacyclohexyl group and an N-methyl-3,3,5,5-tetramethylazacyclohexyl group;

nitrogen-containing aromatic heterocyclic groups such as a pyridyl group, a pyrazyl group, a pyrimidyl group, a pyridazyl group, a quinolyl group and an isoquinolyl group; and the like.

R^{A} represents preferably a tertiary amino group, and more preferably a dimethylamino group.

In the above formula (i), n is preferably 0 to 2, and more preferably 0 or 1.

Examples of the structural unit (I) include structural units represented by the following formulae (I-1) to (I-12) (hereinafter, may be also referred to as “structural units (I-1) to (I-12)”) and the like.

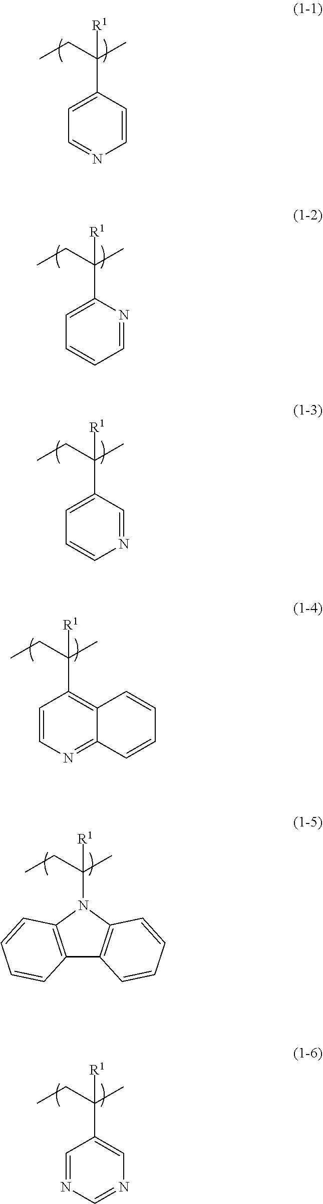

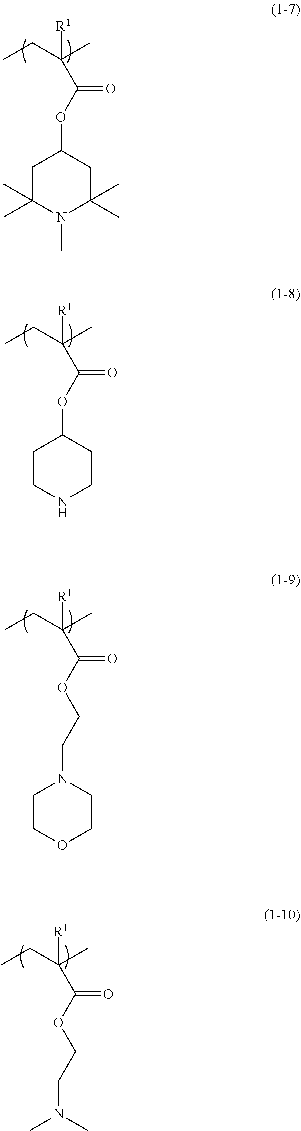

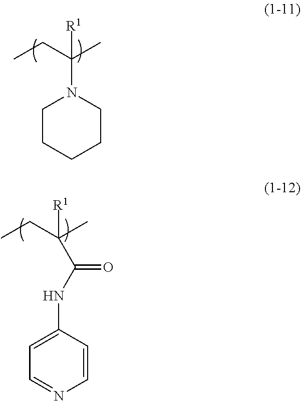

In the above formulae (I-1) to (I-12), R¹ is as defined in the above formula (1).

Of these, the structural unit (I-10) is preferred.

Examples of a monomer that gives the structural unit (I) include:

vinyl compounds each including the side chain group (I), such as vinyl pyridine, vinyl pyrazine and vinyl quinoline;

styrene compounds each including the side chain group (I), such as aminostyrene and dimethylaminostyrene;

(meth)acrylic esters each including the side chain group (I), such as dimethylaminoethyl (meth)acrylate, diethylaminoethyl (meth)acrylate and N-methyl-3,3,5,5-tetramethylazacyclohexan-1-yl (meth)acrylate; and the like.

The lower limit of the content of the structural unit (I) is preferably 0.1 mol %, more preferably 0.5 mol %, still more preferably 1 mol %, and particularly preferably 2 mol %. The upper limit of the content is preferably 30 mol %, more preferably 20 mol %, still more preferably 10 mol %, and particularly preferably 5 mol %. When the content of the structural unit (I) falls within the above range, the film thickness and the density of the cover film can be further increased.

The structural unit (I) is preferably aligned in a block. The block of the structural unit (I) is included in the polymer (A) preferably in at least one end of the main chain, and more preferably in one end of the main chain. When the polymer (A) has the block of the structural unit (I) at one end of the main chain, the film thickness and the density of the cover film can be further increased.

Terminal Group (I)

The terminal group (I) is a monovalent organic group that bonds to at least one end of the main chain of and contains the nitrogen atom of the polymer (A).

The terminal group (I) is exemplified by —R^{X}, —S—R^{X}, wherein R^{X} represents a group including a nitrogen atom, and the like. Examples of R^{X} include groups similar to those exemplified as the side chain group (I), and the like.

The terminal group (I) is preferably —S—R^{X}, and more preferably a dimethylaminoethylsulfanyl group or an aminoethylsulfanyl group.

It is preferred that the polymer (A) has the terminal group (I) at one end of the main chain.

Structural Unit (II)

The structural unit (II) is a structural unit derived from a vinyl aromatic compound, a structural unit derived from (meth)acrylic acid or a (meth)acrylic acid ester, or a combination thereof. The vinyl aromatic compound is exemplified by a substituted or unsubstituted styrene, a substituted or unsubstituted vinyl naphthalene, a substituted or unsubstituted vinyl anthracene, a substituted or unsubstituted vinyl pyrene, and the like.

Examples of the structural unit derived from the vinyl aromatic compound include a structural unit represented by the following formula (2-1) (hereinafter, may be also referred to as “structural unit (II-1)”) and the like. Examples of the structural unit derived from (meth)acrylic acid or a (meth)acrylic acid ester include a structural unit represented by the following formula (2-2) (hereinafter, may be also referred to as “structural unit (II-2)”) and the like.

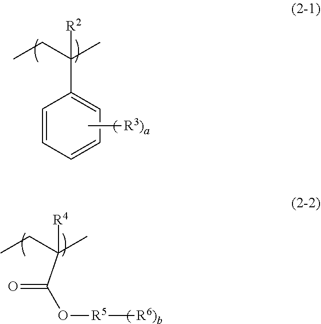

In the above formula (2-1), R² represents a hydrogen atom, a methyl group, a fluorine atom or a trifluoromethyl group; and “a” is an integer of 0 to 5, wherein: in a case in which “a” is 1, R³ represents a hydroxy group, a halogen atom or a monovalent organic group having 1 to 20 carbon atoms; or in a case in which “a” is no less than 2, a plurality of R³s are identical or different, and represent a hydroxy group, a halogen atom or a monovalent organic group having 1 to 20 carbon atoms, or a plurality of R³ taken together represent a part of a ring structure having 4 to 20 ring atoms together with the carbon chain to which the plurality of R³ bond.

In the above formula (2-2), R⁴ represents a hydrogen atom, a methyl group, a fluorine atom or a trifluoromethyl group; R⁵ represents a single bond or a hydrocarbon group having 1 to 20 carbon atoms and having a valency of (1+b); and b is an integer of 1 to 3, wherein: in a case in which R⁵ represents a single bond, b is 1, and in a case in which b is 1, R⁶ represents a hydrogen atom or a monovalent group having a hetero atom; or in a case in which b is no less than 2, a plurality of R⁶s are identical or different and each represent a hydrogen atom or a monovalent group having a hetero atom, or the plurality of R⁶s taken together represent a part of a ring structure having 4 to 20 ring atoms together with the carbon atom or the carbon chain to which the plurality of R⁶s bond.

In light of a degree of copolymerization of a monomer that gives the structural unit (II), R² represents preferably a hydrogen atom or a methyl group, and more preferably a hydrogen atom.

In light of the degree of copolymerization of the monomer that gives the structural unit (II), R⁴ represents preferably a hydrogen atom or a methyl group, and more preferably a methyl group.

The monovalent organic group having 1 to 20 carbon atoms which may be represented by R³ is exemplified by a monovalent hydrocarbon group having 1 to 20 carbon atoms, a carboxy group, a cyano group, and the like.

Examples of the ring structure having 4 to 20 ring atoms which may be represented taken together by a plurality of R³s include: alicyclic structures such as a cyclopentane structure and a cyclohexane structure; aromatic ring structures such as a benzene structure and a naphthalene structure; and the like.

In the above formula (2-1), “a” is preferably 0 to 2, more preferably 0 or 1, and still more preferably 0.

Examples of the hydrocarbon group having 1 to 20 carbon atoms and having a valency of (1+b) which may be represented by R⁵ include groups obtained by removing “b” hydrogen atoms from the monovalent hydrocarbon group exemplified for A in the above formula (1) provided that 1 to 20 carbon atoms are included, and the like.

In the above formula (2-2), b is preferably 1 or 2, and more preferably 1.

Examples of the monovalent group having the hetero atom which may be represented by R⁶ include:

a group having an oxygen atom, such as a hydroxy group or a hydroxymethyl group;

a group having a sulfur atom, such as a sulfanyl group or a sulfanyl methyl group;

a group having a fluorine atom, such as a fluorine atom or a trifluoromethyl group; and the like.

Examples of the ring structure having 4 to 20 ring atoms which may be represented taken together by a plurality of R⁶s include: alicyclic structures such as a cyclopentane structure and a cyclohexane structure; aromatic ring structures such as a benzene structure and a naphthalene structure; and the like.

The structural unit (II) is exemplified by: a structural unit (II-1) such as structural units represented by the following formulae (2-1-1) to (2-1-4) (hereinafter, may be also referred to as “structural units (II-1-1) to (II-1-4)”); a structural unit (II-2) such as structural units represented by the following formulae (2-2-1) to (2-2-6) (hereinafter, may be also referred to as “structural units (II-2-1) to (II-2-6)”); and the like.

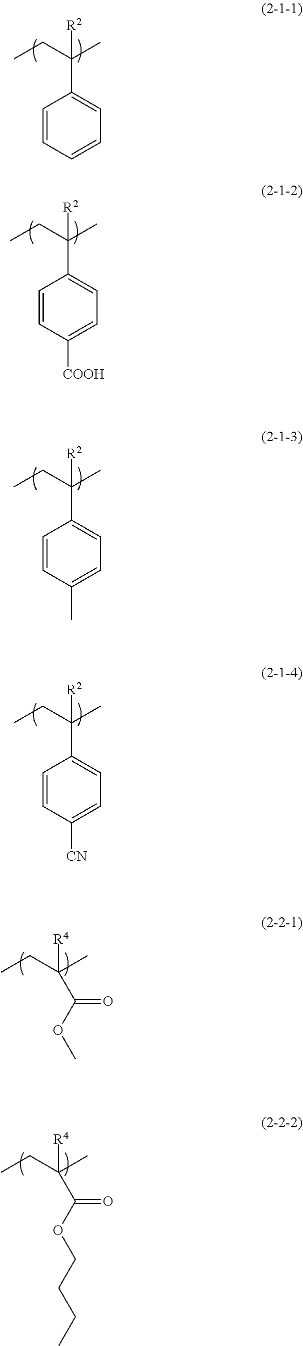

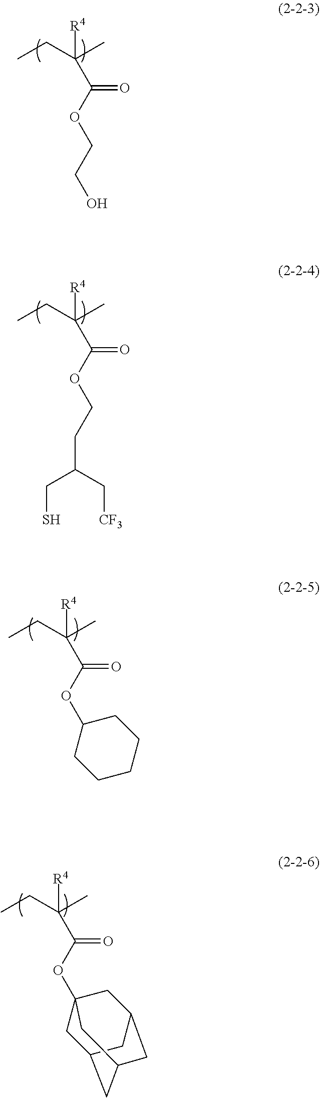

In the above formulae (2-1-1) to (2-1-4), R² is as defined in the above formula (2-1).

In the above formulae (2-2-1) to (2-2-6), R⁴ is as defined in the above formula (2-2).

Of these, the structural unit (II-1-1) is preferred.

In the case in which the polymer (A) has the structural unit (II), the lower limit of the content of the structural unit (II) is preferably 5 mol %, more preferably 50 mol %, still more preferably 80 mol %, particularly preferably 90 mol %, and further particularly preferably 95 mol %. The upper limit of the content is, for example, 100 mol %, preferably 99.9 mol %, more preferably 99 mol %, and still more preferably 98 mol %. When the content of the structural unit (II) falls within the above range, desorption/adsorption performance and mask performance can be further improved.

Other Structural Units

The other structural unit aside from the structural unit (I) and structural unit (II) is exemplified by a structural unit derived from a substituted or unsubstituted ethylene, and the like (wherein the structural unit (I) and the structural unit (II) are excluded).

In the case in which the polymer (A) has the other structural unit(s), the upper limit of the content of the other structural unit is preferably 10 mol %, more preferably 5 mol %, and still more preferably 1 mol %. The lower limit of the content of the other structural unit is, for example, 0.1 mol %.

Other Terminal Group

In addition to the terminal group (I), the polymer (A) may also have another terminal group that bonds to at least one end of the main chain. Examples of the other terminal group include monovalent groups that include a cyano group, a sulfanyl group, an ethylenic carbon-carbon double bond-containing group, an oxazoline ring-containing group, a phosphoric acid group, an epoxy group, a disulfide group or the like; and the like.

Synthesis Procedure of Polymer (A)

The polymer (A) may be synthesized by, for example, using the monomer that gives the structural unit (I), and as needed the monomer that gives the structural unit (II), etc. to permit polymerization through anionic polymerization, cationic polymerization, radical polymerization or the like in an appropriate solvent. Of these, in order to obtain a polymer having the block of the structural unit (I), anionic polymerization is preferred, and living anionic polymerization is more preferred. In order to obtain a random copolymer, radical polymerization is preferred.

Examples of the anionic polymerization initiator which may be used in the living anionic polymerization include:

alkyl lithium, alkylmagnesium halide, sodium naphthalenide, and alkylated lanthanoid compounds;

potassium alkoxides such as t-butoxy potassium;

alkyl zinc such as dimethyl zinc;

alkyl aluminum such as trimethyl aluminum;

aromatic metal compounds such as benzyl potassium; and the like. Of these, alkyl lithium is preferred.

Examples of the solvent which may be used in the living anionic polymerization include:

alkanes such as n-hexane;

cycloalkanes such as cyclohexane;

aromatic hydrocarbons such as toluene;

saturated carboxylic acid esters such as ethyl acetate, n-butyl acetate, i-butyl acetate and methyl propionate;

ketones such as 2-butanone and cyclohexanone;

ethers such as tetrahydrofuran and dimethoxyethane; and the like. One, or two or more types of these solvents may be used.

The reaction temperature in the living anionic polymerization may be appropriately selected in accordance with the type of the anionic polymerization initiator. The lower limit of the reaction temperature is preferably −150° C., and more preferably −80° C., whereas the upper limit of the reaction temperature is preferably 50° C., and more preferably 40° C. The lower limit of the reaction time period is preferably 5 min, and more preferably 20 min. The upper limit of the reaction time period is preferably 24 hrs, and more preferably 12 hrs.

Examples of the radical polymerization initiator which may be used in the radical polymerization include: azo-based radical initiators such as azobisisobutyronitrile (AIBN) and 2,2′-azobis(4-methoxy-2,4-dimethylvaleronitrile); peroxide-based radical initiators such as benzoyl peroxide and cumene hydroperoxide; and the like. Of these, AIBN or dimethyl 2,2′-azobisisobutyrate is preferred, and AIBN is more preferred. These radical polymerization initiators may be used either alone, or as a mixture of two or more types thereof.

Examples of the solvent which may be used in the radical polymerization include solvents exemplified in the case of the living anionic polymerization described above, and the like.

The lower limit of the reaction temperature in the radical polymerization is preferably 40° C., and more preferably 50° C. The upper limit of the reaction temperature is preferably 150° C., and more preferably 120° C. The lower limit of the reaction time period in the polymerization is preferably 1 hour, and more preferably 2 hrs. The upper limit of the reaction time period is preferably 48 hrs, and more preferably 24 hrs.

The polymer (A) formed by the polymerization is preferably recovered by a reprecipitation technique. More specifically, after completion of the reaction, the reaction liquid is charged into a reprecipitation solvent to recover the intended polymer in a powder form. As the reprecipitation solvent, alcohol, ultra pure water, alkane or the like may be used alone or as a mixture of two or more types thereof. Aside from the reprecipitation technique, a liquid separation operation, a column operation, an ultrafiltration operation or the like may be employed to recover the polymer by removing low-molecular weight components such as monomers and oligomers.

The lower limit of a number average molecular weight (Mn) of the polymer (A) is preferably 1,000, more preferably 2,000, still more preferably 3,000, and particularly preferably 4,000. The upper limit of the Mn is preferably 100,000, more preferably 70,000, still more preferably 50,000, and particularly preferably 30,000.

The upper limit of a ratio (dispersity index) of a weight average molecular weight (Mw) to the Mn of the polymer (A) is preferably 5, more preferably 2, still more preferably 1.5, and particularly preferably 1.1. The lower limit of the ratio is typically 1, and preferably 1.05.

The lower limit of the content of the polymer (A) with respect to the total solid content of the composition (I) is preferably 60% by mass, more preferably 80% by mass, still more preferably 90% by mass, and particularly preferably 95% by mass. The upper limit of the content is, for example, 100% by mass. The “total solid content” as referred to herein means the sum of components other than the solvent (B) in the composition (I).

(B) Solvent

The solvent (B) is not particularly limited as long as it is capable of dissolving or dispersing at least the polymer (A) and other component(s), etc.

The solvent (B) is exemplified by an alcohol solvent, an ether solvent, a ketone solvent, an amide solvent, an ester solvent, a hydrocarbon solvent, and the like.

Examples of the alcohol solvent include:

monohydric alcohol solvents such as methanol and ethanol;

polyhydric alcohol solvents such as ethylene glycol and 1,2-propylene glycol;

polyhydric alcohol partial ether solvents such as ethylene glycol monomethyl ether, ethylene glycol monoethyl ether, propylene glycol monomethyl ether and propylene glycol monoethyl ether;

lactic acid ester solvents such as methyl lactate, ethyl lactate, n-butyl lactate and n-amyl lactate; and the like.

Examples of the ether solvent include:

dialkyl ether solvents such as diethyl ether;

cyclic ether solvents such as tetrahydrofuran;

aromatic ring-containing ether solvents such as anisole; and the like.

Examples of the ketone solvent include:

chain ketone solvents such as butanone and methyl-iso-butylketone;

cyclic ketone solvents such as cyclopentanone and cyclohexanone; and the like.

Examples of the amide solvent include:

cyclic amide solvents such as N,N′-dimethylimidazolidinone and N-methylpyrrolidone;

chain amide solvents such as N-methylformamide and N,N-dimethylformamide; and the like.

Examples of the ester solvent include:

acetic acid ester solvents such as ethyl acetate and n-butyl acetate;

polyhydric alcohol partial ether carboxylate solvents such as ethylene glycol monomethyl ether acetate, diethylene glycol monomethyl ether acetate and propylene glycol monomethyl ether acetate;

lactone solvents such as γ-butyrolactone and valerolactone;

carbonate solvents such as ethylene carbonate, propylene carbonate; and the like.

Examples of the hydrocarbon solvent include:

aliphatic hydrocarbon solvents such as n-hexane;

aromatic hydrocarbon solvents such as toluene; and the like.

Of these, the alcohol solvents and/or the ester solvents are preferred, the alcohol solvents are more preferred, the lactic acid ester solvents are still more preferred, and ethyl lactate is particularly preferred. The ester solvent is preferably the polyhydric alcohol partial ether carboxylate solvent, and more preferably propylene glycol monomethyl ether acetate. The composition (I) may contain one, or two or more types of the solvent (B).

Other Components

The other component is exemplified by an acid generating agent or a base generating agent, as well as a crosslinking agent, a surfactant, and the like.

Acid Generating Agent or Base Generating Agent

The acid generating agent is a component capable of generating an acid by an action of heat, a radioactive ray, and/or the like. The base generating agent is a component capable of generating a base by an action of heat, a radioactive ray, and/or the like. In a case in which the composition (I) contains the acid generating agent or the base generating agent, an acid or a base is generated upon irradiation with a radioactive ray, heating by a heating step or the like, etc.; therefore, desorption of portions formed on the region (II) is enabled without using an acidic solution, an alkaline solution or the like as a rinse agent in the desorbing step. The composition (I) may contain one. or two or more types of the acid generating agent or the base generating agent.

The acid generating agent is exemplified by an onium salt compound, an N-sulfonyloxyimide compound, and the like.

Exemplary onium salt compounds include a sulfonium salt, a tetrahydrothiophenium salt, an iodonium salt, an ammonium salt, and the like.

Examples of the sulfonium salt include triphenylsulfonium trifluoromethanesulfonate, triphenylsulfonium nonafluoro-n-butanesulfonate, 4-cyclohexylphenyldiphenylsulfonium trifluoromethanesulfonate, and the like.

Examples of the tetrahydrothiophenium salt include 1-(4-n-butoxynaphthalen-1-yl)tetrahydrothiophenium trifluoromethanesulfonate, 1-(4-n-butoxynaphthalen-1-yl)tetrahydrothiophenium nonafluoro-n-butanesulfonate, and the like.

Examples of the iodonium salt include diphenyliodonium trifluoromethanesulfonate, diphenyliodonium nonafluoro-n-butanesulfonate, diphenyliodonium2-bicyclo[2.2.1]hept-2-yl-1,1,2,2-tetrafluoroethanesulfonate, bis(4-t-butylphenyl)iodonium trifluoromethanesulfonate, and the like.

Examples of the ammonium salt include triethylammonium trifluoromethanesulfonate, triethylammonium nonafluoro-n-butanesulfonate, and the like.

Examples of the N-sulfonyloxyimide compound include N-(trifluoromethanesulfonyloxy)bicyclo[2.2.1]hept-5-ene-2,3-dicarboxyimide and the like.

The acid generating agent is preferably the onium salt compound, more preferably the iodonium salt, and still more preferably bis(4-t-butylphenyl)iodonium nonafluoro-n-butanesulfonate.

Examples of the base generating agent include 4-(methylthiobenzoyl)-1-methyl-1-morpholinoethane, (4-morpholinobenzoyl)-1-benzyl-1-dimethylaminopropane, 2-benzyl-2-dimethylamino-1-(4-morpholinophenyl)-butanone, N-(2-nitrobenzyloxycarbonyl)pyrrolidine, 1-(anthraquinone-2-yl)ethylimidazolecarboxylate, 2-nitrobenzylcyclohexylcarbamate, [[(2,6-dinitrobenzyl)oxy]carbonyl]cyclohexylamine, bis[[(2-nitrobenzyl)oxy]carbonyl]hexane-1,6-diamine, triphenylmethanol, o-carbamoylhydroxylamide, o-carbamoyloxime, hexaamminecobalt (III)tris(triphenylmethylborate), and the like.

In a case in which the composition (I) contains the acid generating agent or the base generating agent, the lower limit of the content of the acid generating agent or base generating agent with respect to 100 parts by mass of the polymer (A) is preferably 0.1 parts by mass, more preferably 0.5 parts by mass, and still more preferably 1% by mass. The upper limit of the content is preferably 20 parts by mass, more preferably 10 parts by mass, and still more preferably 5 parts by mass. When the content of the acid generating agent or base generating agent falls within the above range, selectivity of formation of the cover film can be further improved.

Crosslinking Agent

The crosslinking agent is a component capable of forming a crosslinking bond between components such as the polymer (A), or capable of forming a cross-linked structure per se, by an action of heat, an acid, and/or the like. When the composition (I) contains the crosslinking agent, an increase in hardness of the cover film to be formed is enabled. The composition (I) may contain one, or two or more types of the crosslinking agent.

The crosslinking agent is exemplified by a polyfunctional (meth)acrylate compound, an epoxy compound, a hydroxymethyl group-substituted phenol compound, an alkoxyalkyl group-containing phenol compound, a compound having an alkoxyalkylated amino group, a random copolymer of acenaphthylene and hydroxymethylacenaphthylene, and the like.

Examples of the polyfunctional (meth)acrylate compound include trimethylolpropane tri(meth)acrylate, pentaerythritol tri(meth)acrylate, dipentaerythritol penta(meth)acrylate, and the like.

Examples of the epoxy compound include a novolak-type epoxy resin, a bisphenol type epoxy resin, an alicyclic epoxy resin, an aliphatic epoxy resin, and the like.

Examples of the hydroxymethyl group-substituted phenol compound include 2-hydroxymethyl-4,6-dimethylphenol, 3,5-dihydroxymethyl-4-methoxytoluene (2,6-bis(hydroxymethyl)-p-cresol), and the like.

Examples of the alkoxyalkyl group-containing phenol compound include 4,4′-(1-(4-(1-(4-hydroxy-3,5-bis(methoxymethyl)phenyl)-1-methylethyl)phenyl)ethylidene)bis(2,6-bis(methoxymethyl)phenol and the like.

Examples of the compound having an alkoxyalkylated amino group include (poly)methylol melamine, (poly)methylol glycoluril, and the like.

The crosslinking agent is preferably the alkoxyalkyl group-containing phenol compound, and more preferably 4,4′-(1-(4-(1-(4-hydroxy-3,5-bis(methoxymethyl)phenyl)-1-methylethyl)phenyl)ethylidene)bis(2,6-bis(methoxymethyl)phenol.

In the case in which the composition (I) contains the crosslinking agent, the lower limit of the content of the crosslinking agent with respect to 100 parts by mass of the polymer (A) is preferably 1 part by mass, more preferably 5 parts by mass, still more preferably 10 parts by mass, and particularly preferably 20 parts by mass. The upper limit of the content is preferably 100 parts by mass, more preferably 70 parts by mass, still more preferably 40 parts by mass, and particularly preferably 30 parts by mass. When the content of the crosslinking agent falls within the above range, the hardness of the cover film can be further increased.

Surfactant

The surfactant is a component capable of improving coating properties of the composition (I) on the surface of a base material.

In a case in which the composition (I) contains the surfactant, the upper limit of the content of the surfactant with respect to 100 parts by mass of the polymer (A) is preferably 10 parts by mass, more preferably 2 parts by mass, and still more preferably 1 part by mass. The lower limit of the content is, for example, 0.1 parts by mass.

Preparation Procedure of Composition (I)

The composition (I) may be prepared, for example, by mixing the polymer (A) and the solvent (B), as well as the other component which may be added, in a certain ratio, and preferably filtering a thus resulting mixture through a membrane filter having a pore size of about 200 nm. The lower limit of the solid content concentration of the composition (I) is preferably 0.1% by mass, more preferably 0.5% by mass, and still more preferably 0.7% by mass. The upper limit of the solid content concentration is preferably 30% by mass, more preferably 10% by mass, and still more preferably 3% by mass.

Heating Step

In this step, the coating film (Y) formed by the applying step is heated. It is considered that the metal atom, the nonmetal atom and the like in the region (I) and the region (II) of the base material surface layer would thus interact with the polymer (A) in the composition (I), thereby allowing the coating film (Y) containing the polymer (A) in the region (I) and the region (II) to be laminated.

The means for heating is exemplified by an oven, a hot plate, and the like. The lower limit of the temperature of the heating is preferably 80° C., more preferably 150° C., and still more preferably 180° C. The upper limit of the temperature of the heating is preferably 400° C., more preferably 300° C., and still more preferably 250° C. The lower limit of the heating time period is preferably 10 sec, more preferably 1 min, and still more preferably 3 min. The upper limit of the heating time period is preferably 120 min, more preferably 30 min, and still more preferably 10 min.

It is preferred that in the heating step, the coating film (Y) is washed with an organic solvent such as PGMEA after the heating.

Desorbing Step

In this step, the portion formed on the region (II) of the coating film (Y) after the heating step is desorbed with a rinse agent.

The rinse agent is exemplified by an acidic solution, an alkaline solution, and the like.

Examples of the rinse agent include a composition (hereinafter, may be also referred to as “composition (II)”) prepared by dissolving an acidic compound or a basic compound (hereinafter, may be also referred to as “compound (C)”) in a solvent (hereinafter, may be also referred to as “(D) solvent” or “solvent (D)”), and the like.

Composition (II)

Examples of the compound (C) include:

acidic compounds, e.g., inorganic acids such as hydrochloric acid, nitric acid, sulfuric acid and phosphoric acid; organic acids such as formic acid, acetic acid, benzoic acid and toluenesulfonic acid; and the like, as well as

basic compounds, e.g., inorganic bases such as sodium hydroxide and sodium carbonate; organic bases such as triethylamine, pyridine, 1,4-diazabicyclo[2.2.2]octane (DABCO) and diazabicycloundecene (DBU); and the like.

Of these, the organic acids or the organic bases are preferred, and acetic acid, benzoic acid, toluenesulfonic acid, DABCO or DBU is more preferred.

In a case in which the rinse agent is an acidic solution, greater acidity tends to result in superior regional selectivity in formation of the cover film.

Examples of the solvent (D) include solvents similar to those exemplified as the solvent (B) of the composition (I), as well as water and the like. Of these, the alcohol solvent, the ketone solvent, the ester solvent or water is preferred, the monohydric alcohol solvent, the cyclic ketone solvent, the polyhydric alcohol partial ether carboxylate solvent or water is more preferred, and methanol, cyclohexanone, propylene glycol monomethyl ether acetate or water is still more preferred.

The lower limit of the content of the compound. (C) in the composition (II) is preferably 0.01% by mass, more preferably 0.1% by mass, and still more preferably 0.5% by mass. The upper limit of the content is preferably 10% by mass, more preferably 5% by mass, and still more preferably 3% by mass.

In a contacting procedure of the rinse agent with the surface of the coating film (Y), for example, the rinse agent is placed on the coating film (Y) and left to stand for about 1 min, and desorption is permitted by a spin coater or the like.

The contacting with the rinse agent in the desorbing step may be carried out once, but is preferably carried out at least twice, and more preferably at least three times. By repeating the contacting with the rinse agent multiple times, the desorption of the portions on the region (II) can be further facilitated, thereby enabling a further decrease in film thickness on the region (II).

The average thickness of the cover film to be formed can be a desired value by appropriately selecting: the type and concentration of the polymer (A) in the composition (I); conditions in the heating step such as heating temperature and heating time period; the type and concentration of the rinse agent, and the number of times of repeating the rinsing in the desorbing step; and the like. The lower limit of the film thickness of the cover film in the region (I) is preferably 35 Å, more preferably 50 Å, and still more preferably 60 Å. The upper limit of the film thickness is, for example, 300 Å. The upper limit of the film thickness of the cover film in the region (II) is preferably 50 Å, more preferably 40 Å, and still more preferably 30 Å. The lower limit of the film thickness is, for example, 1 Å.

Accordingly, the method for forming a cover film enables a cover film having a great film thickness and high density to be formed conveniently and highly selectively.

### EXAMPLES

Hereinafter, the present invention is explained in detail by way of Examples, but the present invention is not in any way limited to these Examples. Measuring methods for each physical property are shown below.

Mw and Mn

The Mw and the Mn of the polymer were determined by gel permeation chromatography (GPC) using GPC columns (Tosoh Corporation; “G2000 HXL”×2, “G3000 HXL”×1 and “G4000 HXL”×1) under the following conditions:

eluent: tetrahydrofuran (Wako Pure Chemical Industries, Ltd.);

flow rate: 1.0 mL/min;

sample concentration: 1.0% by mass;

amount of sample injected: 100 μL;

column temperature: 40° C.;

detector: differential refractometer; and

standard substance: mono-dispersed polystyrene.

¹³C-NMR Analysis

A ¹³C-NMR analysis was performed using a nuclear magnetic resonance apparatus (“JNM-EX400” available from JEOL, Ltd.), with DMSO-d₆ used as a solvent for measurement. The proportion of each structural unit contained in the polymer was calculated from an area ratio of a peak corresponding to each structural unit on the spectrum obtained by the ¹³C-NMR.

Synthesis of Polymer (A)

### Synthesis Example 1

### Synthesis of Polymer (A-1)

After a 500-mL flask as a reaction vessel was dried under reduced pressure, 120 g of tetrahydrofuran which had been subjected to a distillation dehydrating treatment in a nitrogen atmosphere was charged, and cooled to −78° C. Thereafter, 2.30 mL (2.30 mmol) of a 1 N cyclohexane solution of sec-butyllithium (sec-BuLi) was charged into this tetrahydrofuran, and then 13.3 mL (0.115 mol) of styrene which had been subjected to: adsorptive filtration by means of silica gel for removing the polymerization inhibitor; and a dehydration treatment by distillation was added dropwise over 30 min. The polymerization system color was ascertained to be orange. During the dropwise addition, the internal temperature of the polymerization reaction mixture was carefully controlled so as not to be −60° C. or higher. After completion of the dropwise addition, aging was permitted for 30 min. Subsequently, 1.0 mL (6.90 mmol) of 1,1-diphenylethylene and 9.2 mL (4.6 mmol) of a 0.5 N tetrahydrofuran solution of lithium chloride were added thereto, and the polymerization system color was ascertained to be dark red. Thereafter, 0.60 mL (3.80 mmol) of N,N-dimethylaminoethyl methacrylate was added thereto and the mixture was stirred for 1 hour. Then, 1 mL of methanol was charged to allow for a terminating reaction of the polymerization end. The temperature of the reaction mixture was elevated to room temperature, and a reaction solution thus obtained was concentrated and replaced with methyl isobutyl ketone. An operation of charging 500 g of ultra pure water to the liquid, stirring the mixture and removing the aqueous underlayer was repeated six times, and then the underlayer was confirmed to be neutral. Thereafter, the solution was concentrated and added dropwise into 500 g of methanol to allow the polymer to be precipitated. The solid was collected on a Buechner funnel. This solid was dried at 60° C. under reduced pressure to give 11.6 g of a white polymer represented by the following formula (A-1).

With respect to this polymer (A-1), the Mw was 5,600, the Mn was 5,100, and the Mw/Mn was 1.09. As determined by the ¹³C-NMR analysis with respect to the proportion of the structural unit contained, a styrene-derived block was 97 mol %, an N,N-dimethylaminoethyl methacrylate-derived block was 3 mol %, revealing that in the polymer (A-1), the N,N-dimethylaminoethyl methacrylate-derived block bonded adjacent to the styrene-derived block, as represented by the following formula (A-1).

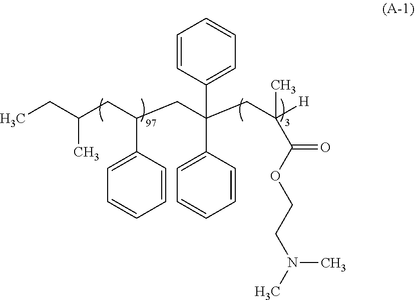

### Synthesis Example 2

### Synthesis of Polymer (A-2)

After a 500-mL flask as a reaction vessel was dried under reduced pressure, 120 g of tetrahydrofuran which had been subjected to a distillation dehydrating treatment in a nitrogen atmosphere was charged, and cooled to −78° C. Thereafter, 0.42 mL (0.41 mmol) of a 1 N cyclohexane solution of sec-butyllithium (sec-BuLi) was charged into this tetrahydrofuran, and then 13.3 mL (0.115 mol) of styrene which had been subjected to: adsorptive filtration by means of silica gel for removing the polymerization inhibitor; and a dehydration treatment by distillation was added dropwise over 30 min. The polymerization system color was ascertained to be orange. During the dropwise addition, the internal temperature of the polymerization reaction mixture was carefully controlled so as not to be −60° C. or higher. After completion of the dropwise addition, aging was permitted for 30 min. Subsequently, 0.17 mL (1.23 mmol) of 1,1-diphenylethylene and 1.64 mL (0.83 mmol) of a 0.5 N tetrahydrofuran solution of lithium chloride were added thereto and the polymerization system color was ascertained to be dark red. Thereafter, 0.60 mL (3.80 mmol) of N,N-dimethylaminoethyl methacrylate was added thereto and the mixture was stirred for 1 hour. Then, 1 mL of methanol was charged to allow for a terminating reaction of the polymerization end. The temperature of the reaction mixture was elevated to room temperature, and a reaction solution thus obtained was concentrated and replaced with methyl isobutyl ketone. An operation of charging 500 g of ultra pure water to the liquid, stirring the mixture and removing the aqueous underlayer was repeated six times, and then the aqueous layer was confirmed to be neutral. Thereafter, the solution was concentrated and added dropwise into 500 g of methanol to allow the polymer to be precipitated. The solid was collected on a Buechner funnel. This solid was dried at 60° C. under reduced pressure to give 11.3 g of a white polymer represented by the following formula (A-2).

With respect to this polymer (A-2), the Mw was 30,000, the Mn was 28,000, and the Mw/Mn was 1.07. As determined by the ¹³C-NMR analysis with respect to the proportion of the structural unit contained, a styrene-derived block was 97 mol % and an N,N-dimethylaminoethyl methacrylate-derived block was 3 mol %, revealing that in the polymer (A-2), the N,N-dimethylaminoethyl methacrylate-derived block bonded adjacent to the styrene-derived block, as represented by the following formula (A-2).

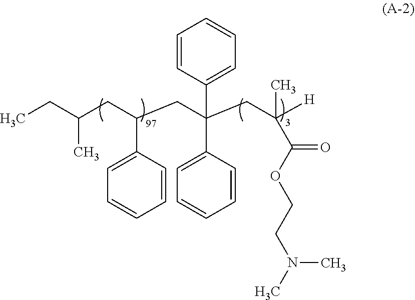

Preparation of Composition (I)

The polymer (A) and the solvent (B) used for preparing the composition (I) are as presented below.

(A) Polymer

A-1: Polymer synthesized in Synthesis Example 1 (Mn=5,100, Mw/Mn=1.09)

A-2: Polymer synthesized in Synthesis Example 2 (Mn=28,000, Mw/Mn=1.07)

A-3: ω-thiol-end polystyrene (manufactured by Polymer Source, Inc., Sample#: P4430-SSH, Mn=5,300, Mw/Mn=1.10)

A-4: ω-thiol-end polystyrene (manufactured by Polymer Source, Inc., Sample#: P8660-SSH, Mn=29,000, Mw/Mn=1.07)

(B) Solvent

B-1: propylene glycol monomethyl ether acetate (PGMEA)

### Preparation Examples 1 to 4

Compositions (I) shown in Table 1 were prepared using the polymer (A) and the solvent (B) of types shown in Table 1 below, by mixing 100 parts by mass of the polymer (A) and 9,900 parts by mass of the solvent (B), and filtering resulting mixed solutions through a membrane filter having a pore size of 200 nm.

TABLE 1

| | (I) Composition | (A) polymer | (B) solvent |
|---|---|---|---|
| Preparation | (I-1) | (A-1) | (B-1) |
| Example 1 | | | |
| Preparation | (I-2) | (A-2) | (B-1) |
| Example 2 | | | |
| Preparation | (I-3) | (A-3) | (B-1) |
| Example 3 | | | |
| Preparation | (I-4) | (A-4) | (B-1) |
| Example 4 | | | |

Preparation of Rinse Agent

The compound (C) and the solvent (D) used for preparing the rinse agent (composition (II)) are as presented below.

(C) Compound

C-1: acetic acid

C-2: benzoic acid

C-3: toluenesulfonic acid

C-4: 1,4-diazabicyclo[2.2.2]octane (DABCO)

C-5: diazabicycloundecene (DBU)

(D) Solvent

D-1: propylene glycol monomethyl ether acetate (PGMEA)

D-2: cyclohexanone

D-3: methanol

D-4: water

### Preparation Examples 5 to 12

Compositions (II) shown in Table 2 were prepared as rinse agents, using the compound (C) and the solvent (D) of types shown in Table 2 below, by mixing 100 parts by mass of the polymer (C) and 9,900 parts by mass of the solvent (D), and filtering resulting mixed solutions through a membrane filter having a pore size of 200 nm.

TABLE 2

| | (II) Composition | (C) Compound | (D) Solvent |
|---|---|---|---|
| Preparation | (II-1) | (C-1) | (D-1) |
| Example 5 | | | |
| Preparation | (II-2) | (C-2) | (D-1) |
| Example 6 | | | |
| Preparation | (II-3) | (C-3) | (D-1) |
| Example 7 | | | |
| Preparation | (II-4) | (C-4) | (D-1) |
| Example 8 | | | |
| Preparation | (II-5) | (C-5) | (D-1) |
| Example 9 | | | |
| Preparation | (II-6) | (C-3) | (D-2) |
| Example 10 | | | |
| Preparation | (II-7) | (C-3) | (D-3) |
| Example 11 | | | |
| Preparation | (II-8) | (C-3) | (D-4) |
| Example 12 | | | |

Formation of Cover Film

### Example 1

A silicon dioxide (SiO₂) substrate as an interlayer insulating film, and a tungsten (W) substrate as a metal film were provided, and the surfaces of the substrates were washed with a 5% by mass aqueous citric acid solution. Subsequently, the composition (I-1) was used to form a film by spin coating (1,500 rpm, for 30 sec), and baking was conducted on a hot plate at 200° C. for 5 min. The substrates were then cooled to room temperature and rinsed with PGMEA. The film thickness of each polymer brush film at this time point was measured by an ellipsometer (“alpha-SE”, available from J.A. Woollam Co.), whereby formation of polymer brush films of 70 Å on W and 57 Å on SiO₂ was verified. On the polymer brush film thus formed, the composition (II-1) as the rinse agent was placed and left to stand for 1 min, followed by spinning at 1,500 rpm for 30 sec, and then washing with PGMEA to conduct a detachment treatment. Subsequently, the film thickness of a finally obtained polymer brush film (cover film) was measured by the aforementioned ellipsometer. The measurement results are shown together in Table 3 below.

### Examples 2 to 8

Cover films were formed in a similar manner to Example 1 except that in place of the composition (II-1), the compositions (II-2) to (II-8) were used as the rinse agent, and the cover films were evaluated. The results of the evaluations are shown together in Table 3 below.

### Comparative Example 1

An SiO₂ substrate as an interlayer insulating film, and a tungsten substrate as a metal film were provided, and the surfaces of the substrates were washed with a 5% by mass aqueous citric acid solution. Subsequently, the composition (I-3) was used to form a film by spin coating (1,500 rpm, for 30 sec), and baking was conducted on a hot plate at 200° C. for 5 min. The substrates were then cooled to room temperature and rinsed with PGMEA to form polymer brush films, which were then evaluated. The results of the evaluations are shown together in Table 3 below.

TABLE 3

| | | | Brush film | Brush film | Difference in brush |
|---|---|---|---|---|---|
| | (I) | (II) | thickness on | thickness on | film thicknesses on |
| | Composition | Composition | W (Å) | SiO₂ (Å) | W and on SiO₂ (Å) |
| Example 1 | (I-1) | (II-1) | 64 | 32 | 32 |
| Example 2 | (I-1) _ | (II-2) | 62 | 17 | 45 |
| Example 3 | (I-1) | (II-3) | 55 | 7 | 48 |
| Example 4 | (I-1) | (II-4) | 55 | 33 | 22 |
| Example 5 | (I-1) | (II-5) | 76 | 27 | 49 |
| Example 6 | (I-1) | (II-6) | 57 | 5 | 52 |
| Example 7 | (I-1) | (II-7) | 65 | 19 | 46 |
| Example 8 | (I-1) | (II-8) | 71 | 15 | 56 |
| Comparative | (I-3) | PGMEA | 31 | 0 | 31 |
| Example 1 | | | | | |

The greater the difference between the polymer brush film thickness on the tungsten (W) substrate and the polymer brush film thickness on the SiO₂ substrate, the more favorably the substrate selectivity can be evaluated.

As is seen from the results shown in Table 3, in the case of using the polymer (A) having a similar molecular weight, the brush density tends to be greater as the polymer brush film thickness on the tungsten substrate is greater.

### Example 9

A silicon dioxide (SiO₂) substrate as an interlayer insulating film, and a tungsten (W) substrate as a metal film were provided, and the surfaces of the substrates were washed with a 5% by mass aqueous citric acid solution. Subsequently, the composition (I-2) was used to form a film with spin coating (1,500 rpm, for 30 sec), and baking was conducted on a hot plate at 200° C. for 5 min. The substrates were then cooled to room temperature and rinsed with PGMEA. The film thickness of each polymer brush film at this time point was measured by an ellipsometer (“alpha-SE”, available from J.A. Woollam Co.), whereby formation of polymer brush films of 143 Å on W and 86 Å on SiO₂ was verified. On the polymer brush film, the composition (II-3) was placed and left to stand for 1 min, followed by spinning at 1,500 rpm for 30 sec, and then rinsing with PGMEA to conduct a detachment treatment. Thereafter, the film thickness of a finally obtained polymer brush film was measured by the ellipsometer. The results are shown in Table 4.

### Example 10

After the detachment treatment was conducted in Example 9, a treatment was conducted again in which the composition (II-3) was placed and left to stand for 1 min, followed by spinning at 1,500 rpm for 30 sec and rinsing with PGMEA. Thereafter, the polymer brush film thickness was measured by ellipsometry. The results are shown together in Table 4.

### Example 11

After the rinsing was carried out in Example 10, a treatment was conducted once again in which the composition (II-3) was placed and left to stand for 1 min, followed by spinning at 1,500 rpm for 30 sec and rinsing with PGMEA. Thereafter, the polymer brush film thickness was measured by ellipsometry. The results are shown together in Table 4.

### Comparative Example 2

An SiO₂ substrate as an interlayer insulating film, and a tungsten substrate as a metal film were provided, and the surfaces of the substrates were washed with a 5% by mass aqueous citric acid solution. Subsequently, the composition (I-4) was used to form a film with spin coating (1,500 rpm, for 30 sec), and baking was conducted on a hot plate at 200° C. for 5 min. The substrates were then cooled to room temperature and rinsed with PGMEA to form polymer brush films, which were then evaluated. The results are shown together in Table 4.

TABLE 4

| | | | Brush film | Brush film | Difference in brush |
|---|---|---|---|---|---|
| | (I) | (II) | thickness on | thickness on | film thicknesses on |
| | Composition | Composition | W (Å) | SiO₂ (Å) | W and on SiO₂ (Å) |
| Example 9 | (I-2) | (II-3) | 134 | 39 | 95 |
| Example 10 | (I-2) | (II-3) | 130 | 9 | 121 |
| Example 11 | (I-2) | (II-3) | 127 | 3 | 124 |
| Comparative | (I-4) | PGMEA | 60 | 0 | 60 |
| Example 2 | | | | | |

As is seen from the results shown in Table 4, by repeatedly bringing the rinse agent into contact in the desorbing step, further reduction in the film thickness in the region (II) was enabled.

The method for forming a cover film of the embodiment of the present invention enables a cover film having a great film thickness and high density to be formed conveniently and highly selectively. Therefore, the method for forming a cover film can be suitably used for working processes of semiconductor devices and the like, for which further progress of miniaturization is expected in the future.

Obviously, numerous modifications and variations of the present invention are possible in light of the above teachings. It is therefore to be understood that within the scope of the appended claims, the invention may be practiced otherwise than as specifically described herein.

What is claimed is:

1. A method for forming a cover film comprising:
applying a composition comprising a first polymer and a solvent on a surface of a base material to form a coating film, the base material comprising a surface layer which comprises a first region and a second region having a surface condition that differs from a surface condition of the first region;
heating the coating film; and
desorbing with a rinse agent a portion of the coating film after the heating, the portion being formed on the second region of the coating film,
wherein the first polymer comprises a first structural unit represented by formula (1), or comprises a monovalent organic group which bonds to at least one end of a main chain of the first polymer and which comprises a nitrogen atom, 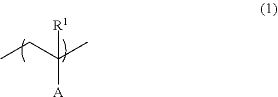
wherein, in the formula (1), R¹ represents a hydrogen atom, a methyl group, a fluorine atom or a trifluoromethyl group; and A represents a monovalent organic group comprising a nitrogen atom.

2. The method according to claim 1, wherein the rinse agent is an acidic solution or an alkaline solution.

3. The method according to claim 1, wherein the first region comprises a metal atom.

4. The method according to claim 1, wherein the second region comprises a silicon atom.

5. The method according to claim 3, wherein the second region comprises a silicon atom.
